(19) United States
(12) Patent Application Publication
(10) Pub. No.: US 2026/0268956 A1
(43) Pub. Date: Sep. 10, 2026

(54) DIGITAL INPUT/OUTPUT CIRCUITRY FOR MEMORY DEVICES

(71) Applicant: Micron Technology, Inc., Boise, ID (US)

(72) Inventors: Simon J. Lovett, Nampa, ID (US); Brent Keeth, Boise, ID (US); Mark Hadrick, Boise, ID (US); James Brian Johnson, Boise, ID (US)

(21) Appl. No.: 19/530,891

(22) Filed: Feb. 5, 2026

Related U.S. Application Data
(60) Provisional application No. 63/766,872, filed on Mar. 4, 2025.

(51) Int. Cl. G11C 11/22; G11C 11/4091; H03K 3/037

(52) U.S. Cl. CPC G11C 11/2273; G11C 11/221; G11C 11/4091; H03K 3/037

(57) ABSTRACT

Methods, systems, and devices for digital input/output (I/O) circuitry for memory devices are described. Circuitry of a memory device may be configured to support outputting results of read commands with various implementations of digital GIO circuitry, which may allow a memory device to refrain from pre-charging an I/O line (e.g., coupled with the GIO circuitry) with a relatively high signal voltage before a latching operation. In some implementations, digital GIO circuitry may include inverter circuitry for generating an output signal associated with performing read commands. The inverter circuitry may raise or lower the voltage of an I/O line with a relatively shorter timing margin compared to analog circuitry techniques (e.g., compared to analog GIO circuitry).

### CROSS REFERENCE

The present Application for Patent claims priority to U.S. Patent Application No. 63/766,872 by Lovett et al., entitled “DIGITAL INPUT/OUTPUT CIRCUITRY FOR MEMORY DEVICES,” filed Mar. 04, 2025, which is assigned to the assignee hereof, and which is expressly incorporated by reference in its entirety herein.

### TECHNICAL FIELD

The following relates to one or more systems for memory, including digital input/output circuitry for memory devices.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports digital input/output circuitry for memory devices in accordance with examples as disclosed herein.

FIGS. 2 and 3 show examples of circuits that support digital input/output circuitry for memory devices in accordance with examples as disclosed herein.

FIG. 4 shows a timing diagram that supports digital input/output circuitry for memory devices in accordance with examples as disclosed herein.

FIG. 5 shows a flowchart illustrating a method or methods that support digital input/output circuitry for memory devices in accordance with examples as disclosed herein.

### DETAILED DESCRIPTION

A memory device may include one or more memory arrays (e.g., one or more arrays of memory cells) and circuitry configured for accessing the one or more memory arrays (e.g., in response to an access command). For example, a memory device may receive a read command from a host (e.g., a host device, a host system) to read a logic state stored by a memory cell of the memory device. To support outputting a result of a read operation responsive to the read command, circuitry of the memory device may implement one or more circuit components (e.g., a local input/output (LIO) component and a global input/output (GIO) component, such as an analog GIO component) configured to bias an input/output (I/O) line with a first voltage indicative of a first logic state (e.g., 1), or with a second voltage indicative of a second logic state (e.g., 0). In some examples, an I/O line may take an amount of time (e.g., a timing margin) to reach a correct voltage state (e.g., a voltage that is below a reference voltage, Vref), which may contribute to a latency associated with reading the logic state. In some memory devices, a timing margin may involve clearing prior data from an I/O line (e.g., coupled with a GIO component) due to a capacitance of the I/O line, or due to a latch (e.g., of the GIO component) supporting a one-way latching operation (e.g., being able to latch a voltage on the I/O line in a decreasing voltage direction but not an increasing voltage direction), or both.

In accordance with aspects disclosed herein, circuitry of a memory device may be configured to support outputting results of read commands with relatively lower latency and power consumption, which may involve implementing digital GIO circuitry. For example, such implementations may allow a memory device to refrain from pre-charging an I/O line (e.g., coupled with the GIO circuitry) with a relatively high signal voltage before a latching operation, which may reduce a latency associated with clearing prior data from the I/O line. In some implementations, a memory device may include inverter circuitry for generating an output signal associated with performing read commands. The inverter circuitry may raise or lower the voltage of an I/O line with a relatively shorter timing margin compared to analog circuitry techniques (e.g., an analog GIO component). In some examples, the described techniques may reduce power consumption as a result of refraining from pre-charging the I/O line, and also may support omitting or simplifying a data sense amplifier (DSA).

In addition to applicability in memory systems as described herein, techniques for digital GIO lines may be generally implemented to improve the performance of various electronic devices and systems (including artificial intelligence (AI) applications, augmented

reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of memory devices and related circuitry. Features of the disclosure are further illustrated and described in the context of flowcharts.

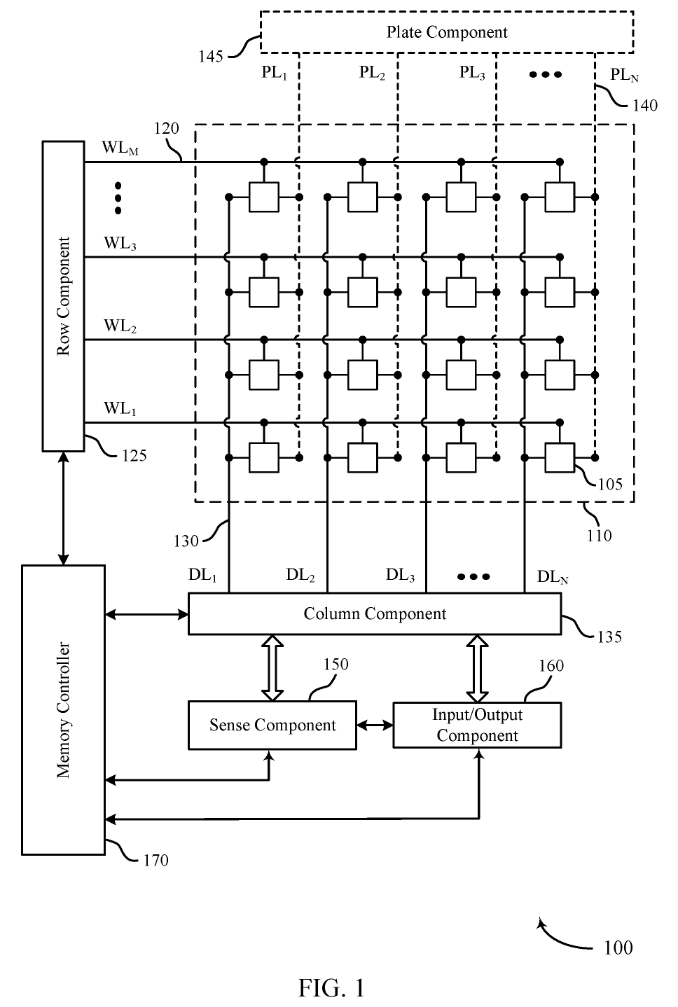

FIG. 1 shows an example of a memory device 100 that supports digital input/output circuitry for memory devices in accordance with examples as disclosed herein. The memory device 100 may be referred to as a memory die or an electronic memory apparatus. The memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array 110 (e.g., a memory array) of the memory device 100, where, in some examples, an array 110 may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In some examples, a memory cell 105 may include or otherwise be associated with a configurable material, which may be referred to as a material memory element, a material storage element, a material portion, and others. The configurable material may have one or more variable and configurable characteristics or properties (e.g., material states) that may represent different logic states. For example, a configurable material may take different forms, different atomic configurations, different degrees of crystallinity, different atomic distributions, or otherwise maintain different characteristics that may be leveraged to represent one logic state or another. In some examples, such characteristics may be associated with different electrical resistances, different threshold characteristics, or other properties that are detectable or distinguishable during a read operation to identify a logic state written to or stored by the configurable material.

In some cases, a configurable material of a memory cell 105 may be associated with a threshold voltage. For example, electrical current may flow through the configurable material when a voltage greater than the threshold voltage is applied across the memory cell 105, and electrical current may not flow through the configurable material, or may flow through the configurable material at a rate below some level (e.g., according to a leakage rate), when a voltage less than the threshold voltage is applied across the memory cell 105. Thus, a voltage applied to memory cells 105 may result in different current flow, or different perceived resistance, or a change in resistance (e.g., a thresholding or switching event) depending on whether a configurable material portion of the memory cell 105 was written with one logic state or another. Accordingly, the magnitude of current, or other characteristic (e.g., thresholding behavior, resistance breakdown behavior, snapback behavior) associated with the current that results from applying a read voltage to the memory cell 105, may be used to determine a logic state written to or stored by memory cell 105.

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target (e.g., selected) memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection component, which, in some examples, may be referred to as a switching component or a selector device of or otherwise associated with the memory cell 105. A word line 120 may be coupled with the cell selection component (e.g., via a control node of the cell selection component), and may control the cell selection component of the memory cell 105. For example, the cell selection component may be a transistor and the word line 120 may be coupled with or be a portion of a gate of the transistor (e.g., where a gate node of the transistor may be a control node of the transistor). Activating a word line 120 may result in an electrical connection (e.g., a closed circuit) between a respective storage component of one or more memory cells 105 and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 of the array 110). For implementations in which a memory cell 105 employs a capacitor for storing a logic state, a digit line 130 may provide access to a first terminal (e.g., a first plate) of the capacitor, and a plate line 140 may provide access to a second terminal (e.g., a second plate) of the capacitor. Although the plurality of plate lines 140 of the memory device 100 are shown as being parallel with the plurality of digit lines 130, in other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all of the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row component 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element).

A memory cell 105 may be read (e.g., sensed) by a sense component 150 when the memory cell 105 is accessed (e.g., in cooperation with the memory controller 170) to determine a logic state written to or stored by the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

To support outputting a result of a read operation, circuitry of a memory device 100 (e.g., of a sense component 150, of an I/O component, or both) may implement one or more circuit components (e.g., a local input/output (LIO) component and a global input/output (GIO) component, such as an analog GIO component) configured to bias an input/output (I/O) line with a first voltage indicative of a first logic state (e.g., 1), or with a second voltage indicative of a second logic state (e.g., 0). In some examples, an I/O line may take an amount of time (e.g., a timing margin) to reach a correct voltage state (e.g., a voltage that is below a reference voltage, Vref), which may contribute to a latency associated with reading the logic state. In some memory devices, a timing margin may involve clearing prior data from an I/O line (e.g., coupled with a GIO component) due to a capacitance of the I/O line, or due to a latch (e.g., of the GIO component) supporting a one-way latching operation (e.g., being able to latch a voltage on the I/O line in a decreasing voltage direction but not an increasing voltage direction), or both.

In accordance with aspects disclosed herein, circuitry of a memory device 100 (e.g., of a sense component 150, of an I/O component, or both) may be configured to support outputting results of read commands with relatively lower latency and power consumption, which may involve implementing digital GIO circuitry (e.g., at an I/O component 160). For example, such implementations may allow a memory device 100 to refrain from pre-charging an I/O line (e.g., coupled with the GIO circuitry) with a relatively high signal voltage before a latching operation, which may reduce a latency associated with clearing prior data from the I/O line. In some implementations, a memory device 100 may include inverter circuitry for generating an output signal associated with performing read commands. The inverter circuitry may raise or lower the voltage of an I/O line with a relatively shorter timing margin compared to analog circuitry techniques (e.g., an analog GIO component). In some examples, the described techniques may reduce power consumption as a result of refraining from pre-charging the I/O line, and also may support omitting or simplifying a data sense amplifier DSA.

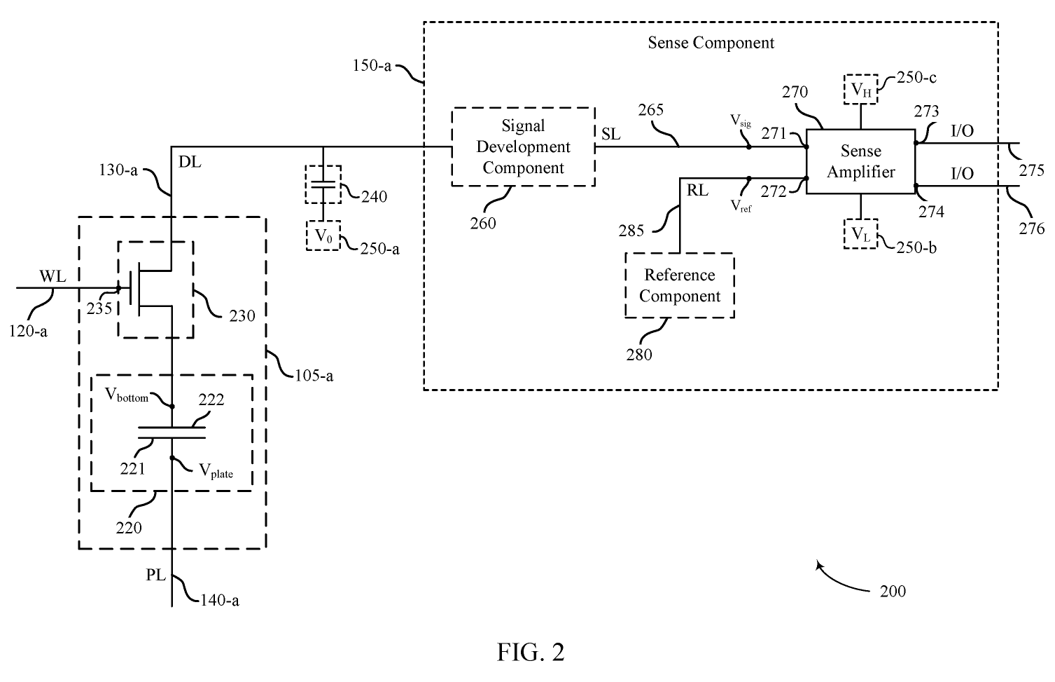

FIG. 2 shows an example of a circuit 200 that supports digital input/output circuitry for memory devices in accordance with examples as disclosed herein. The circuit 200 includes a memory cell 105-a and a sense component 150-a, which may be examples of the respective components as described with reference to FIG. 1. Circuit 200 also includes a word line 120-a, a digit line 130-a, and a plate line 140-a, which may be examples of the respective access lines described with reference to FIG. 1. In various examples, the plate line 140-a may be illustrative of an independently-addressable plate line 140-a, or a common plate node (e.g., of an array 110 that includes the memory cell 105-a). In some memory architectures (e.g., DRAM), the plate line 140-a may be an example of a ground node, such as Vss. In some other memory architectures (e.g., FeRAM), the plate line 140-a may be biased to different voltage levels during different portions of operations performed using the memory cell 105-a.

The memory cell 105-a may include a logic storage component (e.g., a memory element, a storage element, a memory storage element), such as a capacitor 220 that has a first plate, cell plate 221, and a second plate, cell bottom 222. The cell plate 221 and the cell bottom 222 may be capacitively coupled through a dielectric material positioned between them (e.g., in a DRAM application), or capacitively coupled through a ferroelectric material positioned between them (e.g., in a FeRAM application). The cell plate 221 may be associated with a voltage Vₚₗₐₜₑ, and cell bottom 222 may be associated with a voltage V_{bottom}, as illustrated in the circuit 200. The cell plate 221 may be accessed via the plate line 140-a and cell bottom 222 may be accessed via the digit line 130-a. As described herein, various logic states may be stored by charging, discharging, or polarizing the capacitor 220.

The capacitor 220 may be electrically connected with the digit line 130-a, and the stored logic state of the capacitor 220 may be read or sensed by operating various elements represented in circuit 200. For example, the memory cell 105-a may also include a cell selection component 230 which, in some examples, may be referred to as a switching component or a selector device coupled with or between an access line (e.g., the digit line 130-a) and the capacitor 220. In some examples, a cell selection component 230 may be considered to be outside the illustrative boundary of the memory cell 105-a, and the cell selection component 230 may be referred to as a switching component or selector device coupled with or between an access line (e.g., the digit line 130-a) and the memory cell 105-a.

The capacitor 220 may be selectively coupled with the digit line 130-a when the cell selection component 230 is activated (e.g., by way of an activating logical signal), and the capacitor 220 can be selectively isolated from the digit line 130-a when the cell selection component 230 is deactivated (e.g., by way of a deactivating logical signal). A logical signal or other selection signal or voltage may be applied to a control node 235 of the cell selection component 230 (e.g., via the word line 120-a). In other words, the cell selection component 230 may be configured to selectively couple or decouple the capacitor 220 and the digit line 130-a based on a logical signal or voltage applied via the word line 120-a to the control node 235.

Activating the cell selection component 230 may be referred to as selecting or activating the memory cell 105-a, and deactivating the cell selection component 230 may be referred to as deselecting or deactivating the memory cell 105-a. In some examples, the cell selection component 230 is a transistor and its operation may be controlled by applying an activation voltage to the transistor gate (e.g., a control or selection node or terminal). The voltage for activating the transistor (e.g., the voltage between the transistor gate terminal and the transistor source terminal) may be a voltage greater than the threshold voltage magnitude of the transistor. In some examples, activating the cell selection component 230 may be referred to as selectively coupling the memory cell 105-a with the digit line 130-a.

Biasing the plate line 140-a or the digit line 130-a may result in a voltage difference (e.g., the voltage of the digit line 130-a minus the voltage of the plate line 140-a) across the capacitor 220. The voltage difference may accompany a change in the charge stored by the capacitor 220 (e.g., due to charge sharing between the capacitor 220 and the digit line 130-a, due to charge sharing between the capacitor 220 and the plate line 140-a), and the magnitude of the change in stored charge may depend on the initial state of the capacitor 220 (e.g., whether the initial charge or logic state stored a logic 1 or a logic 0).

The digit line 130-a may be coupled with additional memory cells 105 (not shown), and the digit line 130-a may have properties that result in a non-negligible intrinsic capacitance 240 (e.g., on the order of picofarads (pF)), which may couple the digit line 130-a with a voltage source 250-a. The voltage source 250-a may represent a common ground or virtual ground voltage, or the voltage of an adjacent access line of the circuit 200 (not shown). Although illustrated as a separate element in FIG. 2, the intrinsic capacitance 240 may be associated with properties distributed throughout the digit line 130-a.

The sense component 150-a may include a signal development component 260 and a sense amplifier 270 coupled with the signal development component 260 via a signal line 265. In various examples, the signal development component 260 may include circuitry configured to amplify or otherwise convert signals of the digit line 130-a prior to a logic state detection operation (e.g., by the sense amplifier 270). The signal development component 260 may include, for example, a transistor, an amplifier, a cascode, or any other circuitry configured to develop a signal for sensing a logic state stored by the memory cell 105-a. In some examples, the signal development component 260 may include a charge transfer sensing amplifier, which may include one or more transistors in a cascode or voltage control configuration.

Although the digit line 130-a and the signal line 265 are identified as separate lines, the digit line 130-a, the signal line 265, and any other lines connecting a memory cell 105 with a sense amplifier 270 may be referred to as a single access line (e.g., of or associated with the memory cell 105). Constituent portions of such an access line may be identified separately for the purposes of illustrating intervening components and intervening signals in various example configurations.

The sense amplifier 270 may include a first node 271 and a second node 272 which, in some examples, may be coupled with different access lines of a circuit (e.g., a signal line 265 and a reference line 285 of the circuit 200, respectively) or, in other examples, may be coupled with a common access line of a different circuit (not shown). In some examples, the first node 271 may be referred to as a signal node, and the second node 272 may be referred to as a reference node. However, other configurations of access lines or reference lines may be used to support the techniques described herein.

The sense amplifier 270 may include various transistors or amplifiers to detect, convert, or amplify a difference in signals, which may be referred to as latching. For example, the sense amplifier 270 may include circuit elements that receive and compare a sense signal voltage (e.g., V_{sig}, of the signal line 265) at a first node 271 with a reference signal voltage (e.g., V_{ref}, of a reference line 285) at a second node 272. A voltage of the first node 271 may be based on accessing the memory cell 105-a, such as a voltage based at least in part on a charge transfer of the capacitor 220 while the cell selection component 230 is activated. In some examples, a voltage of the second node 272 may be provided by a reference component 280 (e.g., a reference voltage source). In some other examples, a reference voltage may be provided, for example, by accessing the memory cell 105 a to generate the reference voltage (e.g., in a self-referencing access operation), or by accessing a second memory cell 105 (e.g., a complementary memory cell 105) to generate the reference voltage (e.g., in a paired or complementary memory cell access operation), in which case at least a portion of the reference component 280 may be included as part of a signal development component 260, or at least a portion of the reference component 280 may be omitted. An output of the sense amplifier 270 may be driven to a relatively higher voltage (e.g., a positive voltage) or a relatively lower voltage (e.g., a negative voltage, a ground voltage) based on the comparison at the sense amplifier 270.

The sense amplifier 270 may output a detected logic state via one or more I/O lines 275 (e.g., an I/O line 275, an I/O line 276) based on a comparison of signals at the first node 271 and the second node 272. For example, if the first node 271 has a lower voltage than the second node 272, an output of the sense amplifier 270 may be driven to a relatively lower voltage of a first sense amplifier voltage source 250-b (e.g., a voltage of V_{L,} which may be a ground voltage substantially equal to V₀ or a negative voltage). If the first node 271 has a higher voltage than the second node 272, an output of the sense amplifier 270 may be driven to the voltage of a second sense amplifier voltage source 250-c (e.g., a voltage of V_{H}). The sense component 150-a may latch the output of the sense amplifier 270 to determine the logic state stored in the memory cell 105-a (e.g., latching or determining a logic 0 if the first node 271 has a lower voltage than the second node 272, latching or determining a logic 1 if the first node 271 has a higher voltage than the second node 272). The latched output of the sense amplifier 270, corresponding to the detected logic state of memory cell 105-a, may be output via one or more I/O lines (e.g., I/O lines 275 and 276), which may include an output through a column component 135 or an input/output component 160 described with reference to FIG. 1. In some examples, the sense amplifier 270 may be coupled with the I/O line 275 and the I/O line 276 via a node 273 and a node 274, respectively, which may involve one or more switching components (not shown).

To perform a write operation on the memory cell 105-a, a voltage may be applied across the capacitor 220 by controlling the voltage of the cell plate 221 (e.g., through the plate line 140-a) and the cell bottom 222 (e.g., through the digit line 130-a). For example, to write a logic 0, the cell plate 221 may be taken low (e.g., grounding the plate line 140-a, virtually grounding the plate line 140-a, applying a negative voltage to the plate line 140-a), and the cell bottom 222 may be taken high (e.g., applying a positive voltage to the digit line 130-a). The opposite process may be performed to write a logic 1, where the cell plate 221 is taken high and the cell bottom 222 is taken low. In some cases, the voltage applied across the capacitor 220 during a write operation may have a magnitude equal to or greater than a saturation voltage of a ferroelectric material in the capacitor 220, such that the capacitor 220 is polarized, and thus maintains a charge even when the magnitude of applied voltage is reduced, or if a zero net voltage is applied across the capacitor 220.

The circuit 200, including the sense amplifier 270, the cell selection component 230, the signal development component 260, or the reference component 280, may include various types of transistors. For example, the circuit 200 may include n-type transistors, where applying a relative positive voltage to the gate of the n-type transistor that is above a threshold voltage for the n-type transistor (e.g., an applied voltage having a positive magnitude, relative to a source terminal, that is greater than a threshold voltage) enables a conductive path between the other terminals of the n-type transistor (e.g., a drain terminal and the source terminal, across a conduction channel).

In some examples, the n-type transistor may act as a switching component, where the applied voltage is a logical signal that is used to enable conductivity through the transistor by applying a relatively high logical signal voltage (e.g., a voltage corresponding to a logic 1 state, which may be associated with a positive logical signal voltage supply), or to disable conductivity through the transistor by applying a relatively low logical signal voltage (e.g., a voltage corresponding to a logic 0 state, which may be associated with a ground or virtual ground voltage). In examples in which a n-type transistor is employed as a switching component, the voltage of a logical signal applied to the gate terminal may be selected to operate the transistor at a particular working point (e.g., in a saturation region or in an active region).

In some examples, the behavior of a n-type transistor may be more complex than a logical switching, and selective conductivity across the transistor may also be a function of varying drain and source voltages. For example, the applied voltage at the gate terminal may have a particular voltage level (e.g., a clamping voltage) that is used to enable conductivity between the drain terminal and the source terminal when the source terminal voltage is below a certain level (e.g., below the gate terminal voltage minus the threshold voltage). When the voltage of the source terminal rises above the certain level, the n-type transistor may be deactivated such that the conductive path between the drain terminal and source terminal is opened.

Additionally, or alternatively, the circuit 200 may include p-type transistors, where applying a relative negative voltage to the gate of the p-type transistor that is above a threshold voltage for the p-type transistor (e.g., an applied voltage having a negative magnitude, relative to a source terminal, that is greater than a threshold voltage) enables a conductive path between the other terminals of the p-type transistor (e.g., a drain terminal and the source terminal, across a conductive channel).

In some examples, the p-type transistor may act as a switching component, where the applied voltage is a logical signal that is used to enable conductivity by applying a relatively low logical signal voltage (e.g., a voltage corresponding to a logical “1” state, which may be associated with a negative logical signal voltage supply), or to disable conductivity by applying a relatively high logical signal voltage (e.g., a voltage corresponding to a logical “0” state, which may be associated with a ground or virtual ground voltage). In examples in which a p-type transistor is employed as a switching component, the voltage of a logical signal applied to the gate terminal may be selected to operate the transistor at a particular working point (e.g., in a saturation region or in an active region).

In some examples, the behavior of a p-type transistor may be more complex than a logical switching by the gate voltage, and selective conductivity across the transistor may also be a function of varying drain and source voltages. For example, the applied voltage at the gate terminal may have a particular voltage level that is used to enable conductivity between the drain terminal and the source terminal so long as the source terminal voltage is above a certain level (e.g., above the gate terminal voltage plus the threshold voltage). When the voltage of the source terminal voltage falls below the certain level, the p-type transistor may be deactivated such that the conductive path between the drain terminal and source terminal is opened.

A transistor of the circuit 200 may be a field-effect transistor (FET), including a metal oxide semiconductor FET, which may be referred to as a MOSFET. In some examples, these and other types of transistors may be formed by doped regions of material of a substrate. In some examples, transistors may be formed on a substrate that is dedicated to a particular component of the circuit 200 (e.g., a substrate for the sense amplifier 270, a substrate for the signal development component 260, a substrate for the reference component 280, a substrate for the memory cell 105-a), or the transistor(s) may be formed on a substrate that is common for particular components of the circuit 200 (e.g., a substrate that is common to two or more of the sense amplifier 270, the signal development component 260, the reference component 280, or the memory cell 105-a). Additionally, or alternatively, transistors may be formed above a substrate, including transistors that implement channels along a direction from a substrate (e.g., vertical transistors) or channels along a direction over a substrate. Some FETs may have a metal portion including aluminum or other metal, but some FETs may implement other non-metal materials such as polycrystalline silicon, including those FETs that may be referred to as a MOSFET. Further, although an oxide portion may be used as a dielectric portion of a FET, other non-oxide materials may be used in a dielectric material in a FET, including those FETs that may be referred to as a MOSFET.

Although the circuit 200 illustrates a set of components relative to a single memory cell 105, various components of the circuit 200 may be duplicated in a memory device 100 to support various operations. For example, to support row access or page access operations, a sense component 150 may be configured with multiples of one or more of a signal development component 260, a signal line 265, a reference component 280, a reference line 285, a sense amplifier 270, or other components, where the multiples may be configured according to a quantity of memory cells 105 that may be accessed in a row access or page access operation (e.g., in a concurrent operation).

In accordance with aspects disclosed herein, circuitry coupled with I/O lines 275 and 276 (e.g., of an I/O component 160) may be configured to support outputting results of read commands with relatively lower latency and power consumption, which may involve implementing digital GIO circuitry. For example, such implementations may allow a memory device to refrain from pre-charging an I/O line (e.g., coupled with the GIO circuitry, downstream of I/O lines 275 and 276) with a relatively high signal voltage before a latching operation, which may reduce a latency associated with clearing prior data from the I/O line. In some implementations, such circuitry may include inverter circuitry for generating an output signal associated with performing read commands. The inverter circuitry may raise or lower the voltage of an I/O line with a relatively shorter timing margin compared to analog circuitry techniques (e.g., an analog GIO component). In some examples, the described techniques may reduce power consumption as a result of refraining from pre-charging the I/O line, and also may support omitting or simplifying a DSA.

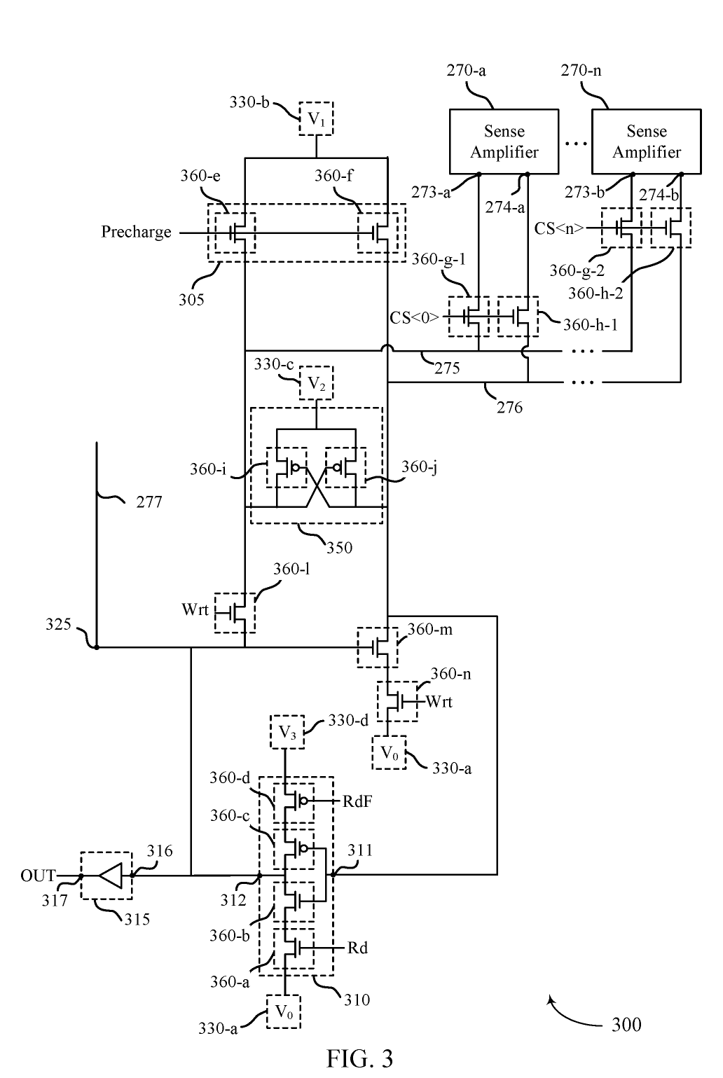

FIG. 3 shows an example of a circuit 300 that supports digital input/output circuitry for memory devices in accordance with examples as disclosed herein. The circuit 300 may be an example of I/O circuitry between one or more sense amplifiers 270 (e.g., sense amplifiers 270-a through 270-n) and a digital output (e.g., via a buffer 315). For example, the circuit 300 may include a component 305 (e.g., a precharge component), a component 350 (e.g., a latch component), and an inverter 310 (e.g., a tri-state inverter), which may be components of an intermediate amplifier between the sense amplifiers 270 and the buffer 315 (e.g., a simplified DSA).

The circuit 300 may include voltage sources 330, which may be coupled with various voltage supplies of a memory device 100 that includes the example circuit 300. A respective voltage source 330 may be coupled with a voltage supply that is regulated or generated at a memory device 100 that includes the circuit 300, or is not regulated or generated at the memory device 100 (e.g., is regulated or otherwise supplied by a host device that is coupled with the memory device 100). In some examples, two or more of the voltage sources 330 may be coupled with the same voltage supply (e.g., a common voltage source), and may be associated with the same voltage level. For example, voltage source(s) 330-a may refer to ground nodes, which may represent nodes that are coupled with or connected with a common grounding point (e.g., a chassis ground, a neutral point, a virtual ground). The ground nodes may be associated with a common reference voltage having a voltage V₀, from which other voltages are defined or otherwise related. The voltage sources 330-b, 330-c, and 330-d may each be associated with a voltage greater than V₀ (e.g., may be associated with positive voltages). In some examples, the voltage sources 330-b, 330-c, and 330-d may be associated with the same voltage, such as each of V₁, V₂, and V₃ being equal to a voltage V_{DD}. In some such examples, V₀ may correspond to a relatively low voltage of digital signaling andV₀ may correspond to a relatively high voltage of digital signaling. However, the circuit 300 may implement voltage sources 330 in accordance with other arrangements and voltage values (e.g., magnitudes, polarities).

The circuit 300 includes transistors 360, which may support various aspects of generating signals (e.g., output signals, read signals, digital signals). For example, one or more of the transistors 360 (e.g., transistors 360-a, 360-b, 360-e, 360-f, 360-g, 360-h, 360-l, 360-m, and 360-n) may be n-type transistors and one or more of the transistors 360 (e.g., transistors 360-c, 360-d, 360-i, and 360-j) may be p-type transistors. In some examples, a transistor 360 may be coupled with or between components to provide a selective coupling, decoupling, connection, disconnection, or isolation functionality. As a switching component, a transistor 360 may have a logical signal applied to a gate node of the transistor 360 to selectively enable or disable a conductive path or channel through the transistor 360. For example, enabling a logical signal (e.g., as a logic 1) at a transistor 360 may enable a conductive path through the transistor 360 (e.g., closing a circuit path), and disabling the logical signal (e.g., as a logic 0) at the transistor 360 may disable a conductive path through the transistor 360 (e.g., opening a circuit path). Logical signals may be provided by a memory controller (not shown), such as a memory controller 170 described with reference to FIG. 1, or any other component of a memory device 100 that supports access operation timing. In some examples, transistors 360 may have different operating characteristics, or different design or fabrication characteristics, than transistors that may be used in switching components. In some examples, transistors 360-l, 360-m, and 360-n may be configured to support write operations (e.g., based on activating a write enable signal Wrt).

The sense amplifiers 270-a through 270-n may each be an example of circuitry configured to generate a signal indicative of a logic state of a memory cell 105 based on comparing a sense signal to a reference signal. Each of the sense amplifiers 270 may include respective nodes 273 and 274 that are operable to couple with an I/O line 275 (e.g., a first I/O line, an LIO line) and an I/O line 276 (e.g., a second I/O line, an LIOF line). For example, sense amplifier 270-a may include a node 273-a operable to couple with the I/O line 275 via a transistor 360-g-1 and a node 274-a operable to couple with the I/O line 276 via a transistor 360-h-1, and so on. A respective output signal generated by the sense amplifier 270-a, for example may be associated with a first voltage at the node 273-a and a second voltage at the node 274-a.

In the circuit 300, an I/O line 277 (e.g., a third I/O line, a GIO line) may be operable to output a logic state stored by a memory cell 105 in accordance with digital signals. In some examples, the I/O line 277 may be coupled with circuitry of the intermediate amplifier via a node 325, which may be associated with a corresponding set of sense amplifiers 270 (e.g., sense amplifiers 270-a through 270-n, arranged as a sense amplifier stripe). The I/O line 277 may be coupled with one or more additional circuit components (e.g., one or more additional pairs of I/O lines 275 and 276, one or more additional sets of sense amplifiers 270, one or more additional components 305, components 350, and inverters 310) via one or more additional nodes 325 (not shown) along the I/O line 275. The I/O line 277 may be coupled with the I/O line 275 via a transistor 360-l (e.g., as a switching component).

To read a logic state stored in a memory cell in accordance with some techniques (e.g., analog GIO techniques), a memory device may be configured to precharge each of an I/O line 275, an I/O line 276, and an I/O line 277 by coupling the I/O lines 275, 276, and 277 with a voltage source. However, such analog GIO techniques may cause latency associated with read commands as a result of various timing margins.

The circuit 300 may be configured for digital GIO techniques that support omitting a precharging of the I/O line 277, among other functionality. For example, the circuit 300 may be configured to precharge the I/O line 275 and the I/O line 276 by coupling the I/O lines 275 and 276 with the voltage source 330-b using the component 305. The voltage source 330-b may bias the I/O line 275 and the I/O line 276 with a voltage (e.g., a voltage V_{DD}). A memory device 100 (e.g., a memory controller 170, a column component 135) may generate a column select voltage (e.g., CS<0>) as an input to the transistor 360-g-1 and the transistor 360-h-1 that couples the I/O line 275 and the I/O line 276 with nodes 273-a and 274-a of the sense amplifier 270-a. The column select voltage may cause a voltage of the I/O line 275 to remain at the first voltage value (e.g., if the memory cell stores a first logic state of 1) or to decrease to a second voltage value (e.g., if the memory cell stores a second logic state of 0).

The I/O lines 275 and 276 may also be coupled with a component 350 including cross-coupled transistors 360-i and 360-j. For example, transistor 360-i may include a channel between the I/O line 275 and the voltage source 330-c and a gate coupled with the I/O line 276, and transistor 360-j may include a channel between the I/O line 276 and the voltage source 330-c and a gate coupled with the I/O line 275. The component 350 may be configured to couple (e.g., latch), based on a voltage of the I/O line 275 and a voltage of the I/O line 276 (e.g., the I/O line having a relatively higher voltage), either the I/O line 275 or the I/O line 276 with voltage source 330-c.

The circuit 300 may also include an inverter 310 (e.g., a tri-state inverter, an enabled inverter) with an input 311 coupled with the I/O line 276 and an output 312 coupled with the I/O line 277. For example, the inverter 310 may include a transistor 360-c with a channel between the third I/O line 277 and a first node, and a transistor 360-d with a channel between the first node and a voltage source 330-d. A gate of the transistor 360-c may be coupled with the I/O line 276, and a gate of the transistor 360-d may be configured to couple with an enable signal RdF (e.g., a read enable signal, an inversion of a read enable signal). The inverter 310 may also include a transistor 360-b with a channel between the I/O line 277 and a second node, and a transistor 360-a with a channel between the second node and a voltage source 330-a (e.g., having a voltage that is lower than the voltage source 330-d). A gate of the transistor 360-b may be coupled with the I/O line 276, and a gate of the transistor 360-a may be configured to couple with an enable signal Rd (e.g., an enable signal that is inverted relative to RdF).

The memory device 100 may generate the enable voltage, Rd (e.g., following a first timing margin), which may be applied to the inverter 310. For example, the read enable voltage may be applied to a gate of transistor 360-a that is coupled with the voltage source 330-a having a voltage (e.g., V₀) that is lower than the precharge voltage. The read enable voltage may be accompanied by an inversion of the read enable voltage, RdF, which may be applied to a gate of the transistor 360-d that is coupled with the voltage source 330-d, having a voltage (e.g., V₃) that may be equal to the precharge voltage. The enable voltage may cause the I/O line 277 to be biased with a voltage value above a reference voltage such as by remaining at the precharge voltage (e.g., if the I/O line 275 is biased with the first voltage) or with a voltage value below the reference voltage (e.g., if the I/O line 275 is biased with the second voltage).

In some examples, the circuit 300 may include a buffer 315 (e.g., an output buffer, a CMOS buffer). The buffer 315 may be configured to output, at an output 317, an indication of the logic state stored by the memory cell from the memory system to a host system based on receiving the output signal from the I/O line 277 at an input 316. For example, based on the voltage of the third I/O line 277, the buffer 315 may output the first voltage indicative of the first logic state or the second voltage indicative of the second logic state. Such techniques may omit or simplify implementations of a DSA, such as omitting another enable or latching trigger that follows a second timing margin associated with a capacitance of the GIO.

Accordingly, techniques described herein may enable a memory device 100 incorporating the circuit 300 to use digital GIO techniques to output a value of a logic state stored in a memory cell 105 (e.g., in response to the memory device receiving a read command from a host). For example, the I/O line 277 may not be precharged via a precharge signal and instead may remain at a voltage state corresponding to a last-read logic state value (e.g., a relatively higher voltage state for a logic state of 1 or a relatively lower voltage state for a logic state of 0) or another indeterminate state until the memory device 100 is triggered to read a logic state from a memory cell 105 that is different form the last-read logic state. Such techniques may decrease timing margins associated with read commands, which may reduce a latency associated with reading logic states. Additionally, such techniques may involve generating relatively fewer signals, which may decrease a power consumption or complexity associated with reading logic states.

The circuit 300 may thus be operable to generate an output signal indicating a logic state stored by a memory cell based on generating one or more signals. For example, a component 305 may couple the I/O line 275 and the I/O line 276 with a voltage source 330-b via a transistor 360-e and a transistor 360-f (e.g., prior to coupling the I/O line 275 and the I/O line 276 with the sense amplifier 270-a). In some examples, the I/O line 275 may couple with the node 273-a of the sense amplifier 270-a based on receiving a column select signal and the I/O line 276 may couple with the node 273-b of the sense amplifier 270-a based on receiving the column select signal (e.g., a signal CS <0> received at gate lines of the transistor 360-g-1 and the transistor 360-h-1 after a first timing margin following coupling the I/O line 275 and the I/O line 276 with the voltage source 330-b). The sense amplifier 270-a may generate an output signal by biasing the I/O line 275 and/or the I/O line 276 to a first voltage indictive of a first logic state stored by the memory cell or a second voltage indicative of a second logic state stored by the memory cell. In some examples, prior to generating a output voltage(s), the circuit 300 may isolate the I/O line 275 and the I/O line 276 from the voltage source 330-b.

In some examples, the inverter 310 may be operable to generate an output signal based on coupling the I/O line 275 and the I/O line 276 with the node 273-a and node 273-b of the sense amplifier 270-a, respectively. For example, based on receiving one or more enable signals (e.g., Rd, RdF), the inverter 310 may bias the I/O line 277 to the first voltage indictive of a first logic state stored by the memory cell or the second voltage indicative of a second logic state stored by the memory cell (e.g., in accordance with the voltage of the I/O line 275 and/or the I/O line 276).

As described herein, the circuit 300 may have a simplified or omitted DSA. Accordingly, the circuit 300 may not use control signals and repeaters associated with a DSA, which may decrease power consumption of the circuit 300 associated with read commands.

Additionally, the circuit 300 may not precharge the I/O line 277, which may further decrease power consumption of the circuit 300 associated with read commands. A read operation using the inverter 310 as described herein may not include a second timing margin associated with biasing the I/O line 277, which may reduce a latency associated with read commands.

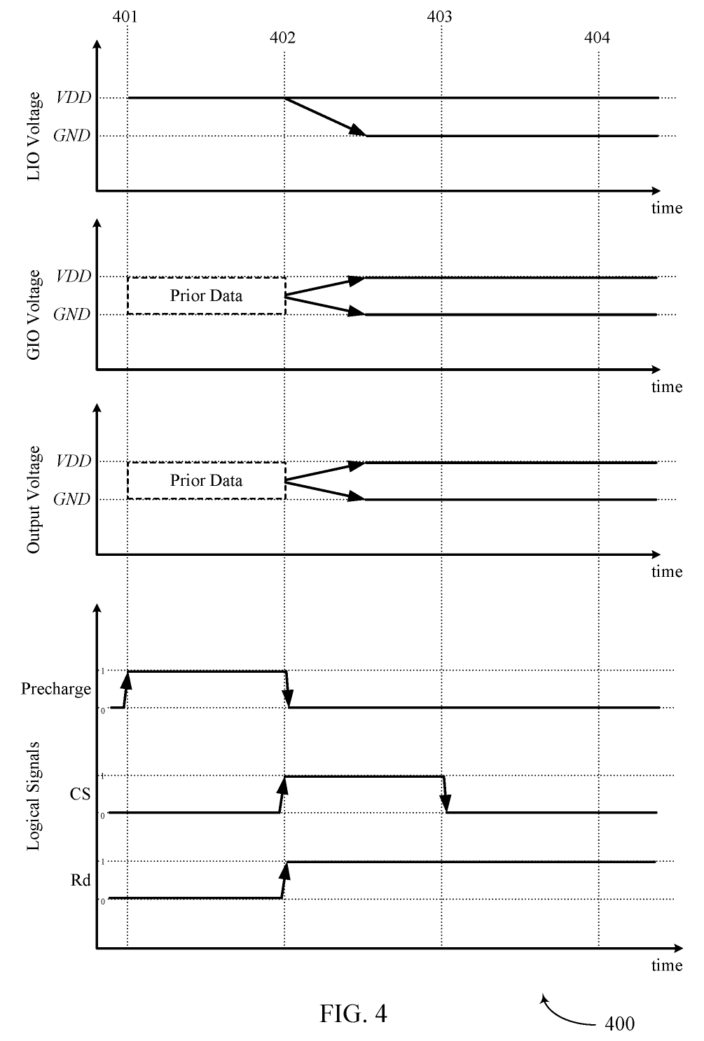

FIG. 4 shows a timing diagram 400 that supports digital input/output circuitry for memory devices in accordance with examples as disclosed herein. The timing diagram 400 may be implemented by a memory device 100 or its components as described herein. For example, timing diagram 400 may be performed by a memory device as described with reference to FIGS. 1 through 3. In some examples, as described with reference to FIG. 3, a memory device 100 may be operable to generate an output signal indicating a logic state stored by a memory cell 105 based on generating one or more signals (e.g., a precharge signal, a column select (CS) signal, a read (Rd) signal) in response to receiving a read command from a host system.

At 401, the memory device 100 may generate a precharge signal. For example, a precharge component may couple a first I/O line (e.g., I/O line 275, LIO) and a second I/O line (e.g., I/O line 276, LIOF) with a voltage source (e.g., voltage source 330-b) via one or more transistors (e.g., transistors 360-e, 360-f).

In some examples, at 402, the memory device 100 may isolate the first I/O line and the second I/O line from the voltage source and may generate one or more additional signals. For example, at 402, the first I/O line and the second I/O line may be coupled with a sense amplifier 270 based on receiving a first column select signal (e.g., CS). The sense amplifier 270 may therefore generate a first output signal by biasing the first I/O line (e.g., LIO) to a first voltage (e.g., VDD) indictive of a first logic state stored by the memory cell 105 or a second voltage (e.g., GND) indicative of a second logic state stored by the memory cell 105.

In some examples, an inverter (e.g., an inverter 310) may be operable to generate a second output signal based on coupling the first I/O line and the second I/O line with the sense amplifier. For example, based on receiving one or more enable signals at 402 (e.g., Rd), the inverter may bias a third I/O line (GIO) to the first voltage indictive of the first logic state stored by the memory cell 105 or the second voltage indicative of the second logic state stored by the memory cell 105 in accordance with the voltage of the first I/O line. The voltage of the third I/O line may accordingly transition from a voltage state associated with prior data read by the memory device to the voltage state associated with the logic state stored by the memory cell.

In some examples, the memory device 100 may include an output buffer (e.g., a buffer 315, a CMOS buffer). The output buffer may be configured to output a third output signal indicative of the logic state stored by the memory cell from the memory system to a host system based on receiving the second output signal from the third I/O line. For example, based on the voltage of the third I/O line, the buffer 315 may output the first voltage indicative of the first logic state or the second voltage indicative of the second logic state. The voltage output by the buffer may transition from a voltage state associated with prior data read by the memory device to the voltage state associated with the logic state stored by the memory cell.

At 403, the memory device 100 may isolate the first I/O line and the second I/O line from the sense amplifier based on removing the column select voltage. Accordingly, at 404, the LIO voltage, the GIO voltage, and the output voltage may remain at a voltage state associated with the first logic state (e.g., a voltage VDD associated with a logic state of 1 stored by the memory cell) or at a voltage state associated with the second logic state (e.g., a voltage GND associated with a logic state of 0 stored by the memory cell).

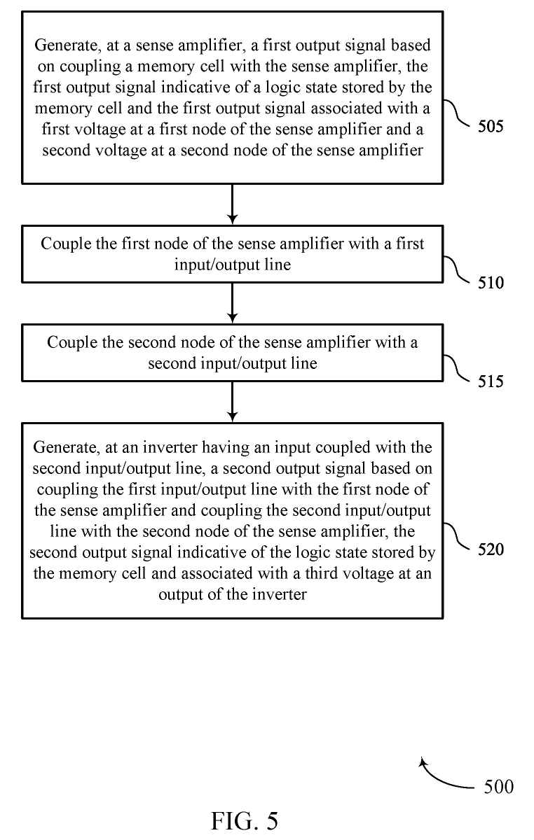

FIG. 5 shows a flowchart illustrating a method 500 that supports digital input/output circuitry for memory devices in accordance with examples as disclosed herein. The operations of method 500 may be implemented by a memory device or its components as described herein. For example, the operations of method 500 may be performed by a memory device as described with reference to FIGS. 1 through 4. In some examples, a memory device may execute a set of instructions to control the functional elements of the device to perform the described functions. Additionally, or alternatively, the memory device may perform aspects of the described functions using special-purpose hardware.

At 505, the method may include generating, at a sense amplifier (e.g., a sense amplifier 270), a first output signal based on coupling a memory cell (e.g., a memory cell 105) with the sense amplifier, the first output signal indicative of a logic state stored by the memory cell and the first output signal associated with a first voltage at a first node (e.g., a node 273) of the sense amplifier and a second voltage at a second node (e.g., a node 274) of the sense amplifier.

At 510, the method may include coupling the first node of the sense amplifier with a first input/output line (e.g., an I/O line 275).

At 515, the method may include coupling the second node of the sense amplifier with a second input/output line (e.g., an I/O line 276).

At 520, the method may include generating, at an inverter (e.g., an inverter 310) having an input (e.g., an input 311) coupled with the second input/output line, a second output signal based on coupling the first input/output line with the first node of the sense amplifier and coupling the second input/output line with the second node of the sense amplifier, the second output signal indicative of the logic state stored by the memory cell and associated with a third voltage at an output (e.g., an output 312) of the inverter.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for generating, at a sense amplifier (e.g., a sense amplifier 270), a first output signal based on coupling a memory cell (e.g., a memory cell 105) with the sense amplifier, the first output signal indicative of a logic state stored by the memory cell and the first output signal associated with a first voltage at a first node (e.g., a node 273) of the sense amplifier and a second voltage at a second node (e.g., a node 274) of the sense amplifier; coupling the first node of the sense amplifier with a first input/output line (e.g., an I/O line 275); coupling the second node of the sense amplifier with a second input/output line (e.g., an I/O line 276); and generating, at an inverter (e.g., an inverter 310) having an input (e.g., an input 311) coupled with the second input/output line, a second output signal based on coupling the first input/output line with the first node of the sense amplifier and coupling the second input/output line with the second node of the sense amplifier, the second output signal indicative of the logic state stored by the memory cell and associated with a third voltage at an output (e.g., an output 312) of the inverter.

Aspect 2: The method, apparatus, or non-transitory computer-readable medium of aspect 1, further including operations, features, circuitry, logic, means, or instructions, or any combination thereof for coupling, before coupling the first node of the sense amplifier with the first input/output line and before coupling the second node of the sense amplifier with the second input/output line, the first input/output line with a voltage source (e.g., a voltage source 330-b) via a first transistor (e.g., a transistor 360-e) and the second input/output line with the voltage source via a second transistor (e.g., a transistor 360-f).

Aspect 3: The method, apparatus, or non-transitory computer-readable medium of aspect 2, further including operations, features, circuitry, logic, means, or instructions, or any combination thereof for isolating, before the second output signal is generated, the first input/output line from the voltage source via the first transistor and the second input/output line from the voltage source via the second transistor.

Aspect 4: The method, apparatus, or non-transitory computer-readable medium of any of aspects 1 through 3, further including operations, features, circuitry, logic, means, or instructions, or any combination thereof for coupling, based on the first voltage and the second voltage, either the first input/output line or the second input/output line with a voltage source (e.g., a voltage source 330-c).

Aspect 5: The method, apparatus, or non-transitory computer-readable medium of any of aspects 1 through 4, where the inverter includes a first p-type transistor (e.g., a transistor 360-c) having a first channel coupled between the output of the inverter and a third node and having a gate coupled with the second input/output line; a second p-type transistor (e.g., a transistor 360-d) having a second channel coupled between the third node and a first voltage source associated with a first source voltage (e.g., a voltage source 330-d); a first n-type transistor (e.g., a transistor 360-b) having a third channel coupled between the output of the inverter and a fourth node and having a third gate coupled with the second input/output line; and a second n-type transistor (e.g., a transistor 360-a) having a fourth channel coupled between the fourth node and a second voltage source (e.g., a voltage source 330-a) associated with a second source voltage that is lower than the first source voltage.

Aspect 6: The method, apparatus, or non-transitory computer-readable medium of aspect 5, where generating the second output signal is based on coupling a second gate of the second p-type transistor with a first enable signal (e.g., RdF); and coupling a fourth gate of the second n-type transistor with a second enable signal (e.g., Rd) that is inverted relative to the first enable signal.

Aspect 7: The method, apparatus, or non-transitory computer-readable medium of any of aspects 1 through 6, further including operations, features, circuitry, logic, means, or instructions, or any combination thereof for generating, at a buffer (e.g., a buffer 315) having an input (e.g., an input 316) coupled with the output of the inverter, a third output signal based on the second output signal, the third output signal indicative of the logic state stored by the memory cell and associated with a fourth voltage at an output (e.g., an output 317) of the buffer.

Aspect 8: The method, apparatus, or non-transitory computer-readable medium of any of aspects 1 through 7, further including operations, features, circuitry, logic, means, or instructions, or any combination thereof for receiving a command to read the logic state stored by the memory cell, where generating the first output signal and the second output signal are in response to the command.

It should be noted that the methods described herein are possible implementations, and that the operations and the steps may be rearranged or otherwise modified and that other implementations are possible. Further portions from two or more of the methods may be combined.

An apparatus is described. The following provides an overview of aspects of the apparatus as described herein:

Aspect 9: An apparatus, including: a sense amplifier (e.g., a sense amplifier 270, such as sense amplifier 270-a) operable to generate a first output signal based on coupling the sense amplifier with a memory cell (e.g., a memory cell 105), the first output signal indicative of a logic state stored by the memory cell and the first output signal associated with a first voltage at a first node (e.g., a node 273) of the sense amplifier and a second voltage at a second node (e.g., a node 274) of the sense amplifier; a first input/output line (e.g., an I/O line 275) operable to couple with the first node of the sense amplifier; a second input/output line (e.g., an I/O line 276) operable to couple with the second node of the sense amplifier; and an inverter (e.g., an inverter 310) having an input (e.g., an input 311) coupled with the second input/output line and having an output (e.g., an output 312) coupled with a third input/output line (e.g., an I/O line 277), the inverter operable to generate a second output signal based on coupling the first input/output line with the first node of the sense amplifier and coupling the second input/output line with the second node of the sense amplifier, the second output signal indicative of the logic state stored by the memory cell and associated with a third voltage at the output of the inverter.

Aspect 10: The apparatus of aspect 9, where the inverter is a tri-state inverter.

Aspect 11: The apparatus of any of aspects 9 through 10, where the inverter includes: a first p-type transistor (e.g., a transistor 360-c) having a first channel coupled between the third input/output line and a third node and having a gate coupled with the second input/output line; a second p-type transistor (e.g., a transistor 360-d) having a second channel coupled between the third node and a first voltage source (e.g., a voltage source 330-c) associated with a first source voltage; a first n-type transistor (e.g., a transistor 360-b) having a third channel coupled between the third input/output line and a fourth node and having a third gate coupled with the second input/output line; and a second n-type transistor (e.g., a transistor 360-a) having a fourth channel coupled between the fourth node and a second voltage source (e.g., a voltage source 330-a) associated with a second source voltage that is lower than the first source voltage.

Aspect 12: The apparatus of aspect 11, where: the second p-type transistor has a second gate configured to couple with a first enable signal (e.g., RdF); and the second n-type transistor has a fourth gate configured to couple with a second enable signal (e.g., Rd) that is inverted relative to the first enable signal.

Aspect 13: The apparatus of any of aspects 9 through 12, further including: a buffer (e.g., a buffer 315) having an input (e.g., an input 316) coupled with the third input/output line and having an output (e.g., an output 317) coupled with a fourth input/output line, the buffer operable to generate a third output signal based on the second output signal, the third output signal indicative of the logic state stored by the memory cell and associated with a fourth voltage at the output of the buffer.

Aspect 14: The apparatus of any of aspects 9 through 13, further including: a circuit component (e.g., a component 350) configured to couple, based on the first voltage and the second voltage, either the first input/output line or the second input/output line with a voltage source (e.g., a voltage source 330-c).

Aspect 15: The apparatus of aspect 14, where the circuit component includes: a first p-type transistor (e.g., a transistor 360-i) having a first channel coupled between the first input/output line and the voltage source and a first gate coupled with the second input/output line; and a second p-type transistor (e.g., a transistor 360-j) having a second channel coupled between the second input/output line and the voltage source and a second gate coupled with the first input/output line.

Aspect 16: The apparatus of any of aspects 9 through 15, further including: a precharge component (e.g., a component 305) configured to couple the first input/output line and the second input/output line with a voltage source (e.g., a voltage source 330-b) before coupling the first input/output line with the first node of the sense amplifier and before coupling the second input/output line with the second node of the sense amplifier.

Aspect 17: The apparatus of any of aspects 9 through 16, further including: a second sense amplifier (e.g., a second sense amplifier 270, such as sense amplifier 270-n) operable to generate a third output signal based on coupling the second sense amplifier with a second memory cell (e.g., a second memory cell 105), the third output signal indicative of a second logic state stored by the second memory cell and the third output signal associated with a fourth voltage at a third node (e.g., a node 273-b) of the second sense amplifier and a fifth voltage at a fourth node (e.g., a node 274-b) of the second sense amplifier, the first input/output line operable to couple with the third node of the second sense amplifier, and the second input/output line operable to couple with the fourth node of the second sense amplifier.

Aspect 18: The apparatus of aspect 17, where: the first input/output line is operable to couple with the first node of the sense amplifier and the second input/output line is operable to couple with the second node of the sense amplifier based on a first column selection signal (e.g., CS<0>); and the first input/output line is operable to couple with the third node of the second sense amplifier and the second input/output line is operable to couple with the fourth node of the second sense amplifier based on a second column selection signal (e.g., CS<n>).

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor’s threshold voltage is applied to the transistor gate. The transistor may be “off” or “deactivated” when a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by

following the reference label by a dash and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a sense amplifier operable to generate a first output signal based on coupling the sense amplifier with a memory cell, the first output signal indicative of a logic state stored by the memory cell and the first output signal associated with a first voltage at a first node of the sense amplifier and a second voltage at a second node of the sense amplifier;
a first input/output line operable to couple with the first node of the sense amplifier;
a second input/output line operable to couple with the second node of the sense amplifier; and
an inverter having an input coupled with the second input/output line and having an output coupled with a third input/output line, the inverter operable to generate a second output signal based on coupling the first input/output line with the first node of the sense amplifier and coupling the second input/output line with the second node of the sense amplifier, the second output signal indicative of the logic state stored by the memory cell and associated with a third voltage at the output of the inverter.

2. The apparatus of claim 1, wherein the inverter is a tri-state inverter.

3. The apparatus of claim 1, wherein the inverter comprises:
a first p-type transistor having a first channel coupled between the third input/output line and a third node and having a gate coupled with the second input/output line;
a second p-type transistor having a second channel coupled between the third node and a first voltage source associated with a first source voltage;
a first n-type transistor having a third channel coupled between the third input/output line and a fourth node and having a third gate coupled with the second input/output line; and
a second n-type transistor having a fourth channel coupled between the fourth node and a second voltage source associated with a second source voltage that is lower than the first source voltage.

4. The apparatus of claim 3, wherein:
the second p-type transistor has a second gate configured to couple with a first enable signal; and
the second n-type transistor has a fourth gate configured to couple with a second enable signal that is inverted relative to the first enable signal.

5. The apparatus of claim 1, further comprising:
a buffer having an input coupled with the third input/output line and having an output coupled with a fourth input/output line, the buffer operable to generate a third output signal based on the second output signal, the third output signal indicative of the logic state stored by the memory cell and associated with a fourth voltage at the output of the buffer.

6. The apparatus of claim 1, further comprising:
a circuit component configured to couple, based on the first voltage and the second voltage, either the first input/output line or the second input/output line with a voltage source.

7. The apparatus of claim 6, wherein the circuit component comprises:
a first p-type transistor having a first channel coupled between the first input/output line and the voltage source and a first gate coupled with the second input/output line; and
a second p-type transistor having a second channel coupled between the second input/output line and the voltage source and a second gate coupled with the first input/output line.

8. The apparatus of claim 1, further comprising:
a precharge component configured to couple the first input/output line and the second input/output line with a voltage source before coupling the first input/output line with the first node of the sense amplifier and before coupling the second input/output line with the second node of the sense amplifier.

9. The apparatus of claim 1, further comprising:
a second sense amplifier operable to generate a third output signal based on coupling the second sense amplifier with a second memory cell, the third output signal indicative of a second logic state stored by the second memory cell and the third output signal associated with a fourth voltage at a third node of the second sense amplifier and a fifth voltage at a fourth node of the second sense amplifier, the first input/output line operable to couple with the third node of the second sense amplifier, and the second input/output line operable to couple with the fourth node of the second sense amplifier.

10. The apparatus of claim 9, wherein:
the first input/output line is operable to couple with the first node of the sense amplifier and the second input/output line is operable to couple with the second node of the sense amplifier based on a first column selection signal; and
the first input/output line is operable to couple with the third node of the second sense amplifier and the second input/output line is operable to couple with the fourth node of the second sense amplifier based on a second column selection signal.

11. A method, comprising:
generating, at a sense amplifier, a first output signal based on coupling a memory cell with the sense amplifier, the first output signal indicative of a logic state stored by the memory cell and the first output signal associated with a first voltage at a first node of the sense amplifier and a second voltage at a second node of the sense amplifier;
coupling the first node of the sense amplifier with a first input/output line;
coupling the second node of the sense amplifier with a second input/output line; and
generating, at an inverter having an input coupled with the second input/output line, a second output signal based on coupling the first input/output line with the first node of the sense amplifier and coupling the second input/output line with the second node of the sense amplifier, the second output signal indicative of the logic state stored by the memory cell and associated with a third voltage at an output of the inverter.

12. The method of claim 11, further comprising:
coupling, before coupling the first node of the sense amplifier with the first input/output line and before coupling the second node of the sense amplifier with the second input/output line, the first input/output line with a voltage source via a first transistor and the second input/output line with the voltage source via a second transistor.

13. The method of claim 12, further comprising:
isolating, before the second output signal is generated, the first input/output line from the voltage source via the first transistor and the second input/output line from the voltage source via the second transistor.

14. The method of claim 11, further comprising:
coupling, based on the first voltage and the second voltage, either the first input/output line or the second input/output line with a voltage source.

15. The method of claim 11, wherein the inverter comprises:
a first p-type transistor having a first channel coupled between the output of the inverter and a third node and having a gate coupled with the second input/output line;
a second p-type transistor having a second channel coupled between the third node and a first voltage source associated with a first source voltage;
a first n-type transistor having a third channel coupled between the output of the inverter and a fourth node and having a third gate coupled with the second input/output line; and
a second n-type transistor having a fourth channel coupled between the fourth node and a second voltage source associated with a second source voltage that is lower than the first source voltage.

16. The method of claim 15, wherein generating the second output signal is based on coupling a second gate of the second p-type transistor with a first enable signal; and coupling a fourth gate of the second n-type transistor with a second enable signal that is inverted relative to the first enable signal.

17. The method of claim 11, further comprising:
generating, at a buffer having an input coupled with the output of the inverter, a third output signal based on the second output signal, the third output signal indicative of the logic state stored by the memory cell and associated with a fourth voltage at an output of the buffer.

18. The method of claim 11, further comprising:
receiving a command to read the logic state stored by the memory cell, wherein generating the first output signal and the second output signal are in response to the command.

19. A memory device, comprising:
one or more memory arrays;
a sense amplifier; and
circuitry coupled with the one or more memory arrays and the sense amplifier, the circuitry configured to cause the memory device to:
generate, at the sense amplifier, a first output signal based on coupling a memory cell of the one or more memory arrays with the sense amplifier, the first output signal indicative of a logic state stored by the memory cell and the first output signal associated with a first voltage at a first node of the sense amplifier and a second voltage at a second node of the sense amplifier;
couple the first node of the sense amplifier with a first input/output line;
couple the second node of the sense amplifier with a second input/output line; and
generate, at an inverter having an input coupled with the second input/output line, a second output signal based on coupling the first input/output line with the first node of the sense amplifier and coupling the second input/output line with the second node of the sense amplifier, the second output signal indicative of the logic state stored by the memory cell and associated with a third voltage at an output of the inverter.

20. The memory device of claim 19, wherein the circuitry is further configured to cause the memory device to:
couple, before coupling the first node of the sense amplifier with the first input/output line and before coupling the second node of the sense amplifier with the second input/output line, the first input/output line with a voltage source via a first transistor and the second input/output line with the voltage source via a second transistor.

21. The memory device of claim 19, wherein the circuitry is further configured to cause the memory device to:
couple, based on the first voltage and the second voltage, either the first input/output line or the second input/output line with a voltage source.

22. The memory device of claim 19, wherein the inverter comprises:
a first p-type transistor have a first channel coupled between the output of the inverter and a third node and having a gate coupled with the second input/output line;
a second p-type transistor having a second channel coupled between the third node and a first voltage source associated with a first source voltage;
a first n-type transistor having a third channel coupled between the output of the inverter and a fourth node and having a third gate coupled with the second input/output line; and
a second n-type transistor having a fourth channel coupled between the fourth node and a second voltage source associated with a second source voltage that is lower than the first source voltage.

23. The memory device of claim 22, wherein the circuitry is configured to cause the memory device to:
generate the second output signal based on coupling a second gate of the second p-type transistor with a first enable signal; and coupling a fourth gate of the second n-type transistor with a second enable signal that is inverted relative to the first enable signal.

24. The memory device of claim 19, wherein the circuitry is further configured to cause the memory device to:
generate, at a buffer having an input coupled with the output of the inverter, a third output signal based on the second output signal, the third output signal indicative of the logic state stored by the memory cell and associated with a fourth voltage at an output of the buffer.

25. The memory device of claim 19, wherein the circuitry is further configured to cause the memory device to:
receive a command to read the logic state stored by the memory cell, wherein generating the first output signal and the second output signal are in response to the command.
